(19) United States
(12) Patent Application Publication
(10) Pub. No.: US 2024/0053671 A1
(43) Pub. Date: Feb. 15, 2024

(54) REFLECTION TYPE MASK BLANK AND PRODUCTION METHOD THEREFOR, AND REFLECTIVE LAYER-INCLUDING SUBSTRATE FOR SAID MASK BLANK

(71) Applicant: AGC Inc., Tokyo (JP)

(72) Inventors: Ryusuke OISHI, Fukushima (JP); Takahiro KIKUCHI, Fukushima (JP)

(73) Assignee: AGC Inc., Tokyo (JP)

(21) Appl. No.: 18/495,839

(22) Filed: Oct. 27, 2023

Related U.S. Application Data
(63) Continuation of application No. PCT/JP2022/019739, filed on May 9, 2022.

(30) Foreign Application Priority Data
May 14, 2021 (JP) 2021-082631

(51) Int. Cl. G03F 1/24; C23C 14/46; C23C 14/14

(52) U.S. Cl. CPC G03F 1/24; C23C 14/46; C23C 14/14

(57) ABSTRACT

A method for producing a reflective mask blank, includes: forming a reflective multilayer film on or above a substrate by using an ion beam sputtering apparatus and a process gas, the ion beam sputtering apparatus accelerating an ion generated by applying a voltage to a grid, and causing the ion to collide with a target to perform sputtering, the process gas including at least one inert gas selected from He, Ne, Ar, Kr, Xe, Rn, and N₂ as an ion source, in which a product of an effective area (cm²) of the grid and a flow rate (sccm) of the process gas supplied to the ion beam sputtering apparatus during film formation is 3600 (cm²·sccm) or less.

### CROSS-REFERENCE TO RELATED APPLICATIONS

This is a bypass continuation of International Patent Application No. PCT/JP2022/019739, filed on May 9, 2022, which claims priority to Japanese Patent Application No. 2021-082631, filed on May 14, 2021. The contents of these applications are hereby incorporated by reference in their entireties.

### TECHNICAL FIELD

The present invention relates to a reflective mask blank, a production method therefor, and a substrate with a reflection layer for the mask blank.

### BACKGROUND ART

In recent years, with the miniaturization of integrated circuits that constitute semiconductor devices, extreme ultra violet (hereinafter referred to as “EUV”) lithography has been studied as an exposure method that can replace exposure techniques using visible light, ultra violet (wavelength: 193 nm to 365 nm), ArF excimer laser light (wavelength: 193 nm), or the like in the related art.

In the EUV lithography, an EUV light having a wavelength shorter than that of the ArF excimer laser light is used as a light source for exposure. An EUV light refers to a light having a wavelength in a soft X-ray region or a vacuum ultraviolet region, specifically a light having a wavelength of about 0.2 nm to 100 nm. As the EUV light, an EUV light having a wavelength of, for example, about 13.5 nm is used.

Since the EUV light is easily absorbed by various substances, a refractive optical system used in the exposure techniques in the related art cannot be used. Therefore, in the EUV lithography, a reflective optical system such as a reflective mask and a mirror is used. In the EUV lithography, a reflective mask is used as a transfer mask.

The mask blank is a pre-patterning laminate used for production of photomasks. The reflective mask blank has a structure in which a reflection layer that reflects EUV light and an absorption layer that absorbs EUV light are formed in this order on or above a substrate made of a glass or the like. As the reflection layer, a reflective multilayer film, whose light reflectance is increased when a layer surface is irradiated with EUV light by alternately laminating a low refractive index layer having a low refractive index with respect to the EUV light and a high refractive index layer having a high refractive index with respect to the EUV light, is generally used. A molybdenum (Mo) layer is generally used as the low refractive index layer and a silicon (Si) layer is generally used as the high refractive index layer in the reflective multilayer film.

For the absorption layer, a material having a high absorption coefficient for EUV light, specifically, for example, a material containing chromium (Cr) or tantalum (Ta) as a main component is used.

In production of the reflective mask blank, for forming the reflective multilayer film and the absorption layer, a sputtering method is preferably used because it is easy to obtain a uniform film thickness, has a short tact time, and is easy to control the film thickness. Here, an ion beam sputtering method is preferably used for forming the high refractive index layer and the low refractive index layer that constitute the reflective multilayer film (Patent Literature 1).

The sputtering method is a film forming method in which a surface of a sputtering target is impacted by charged particles, the sputtered particles are ejected from the target, and the sputtered particles are deposited on or above a substrate disposed opposite the target to form a thin film.

In the case of the ion beam sputtering method, the inside of an apparatus is evacuated to a high vacuum, then a sputtering gas is introduced into an ion source, and thermoelectrons generated from a filament in the ion source collide with the introduced gas and ionize the introduced gas to generate plasma. By applying an electric field to a grid electrode, this plasma is extracted as an ion beam, accelerated, and is caused to collide with a target to perform sputtering.
Patent Literature 1: JP2004-246366A

### SUMMARY OF INVENTION

Unlike a magnetron sputtering method, in the ion beam sputtering method, the extracted ion beam travels straight with a constant diffusion angle. Therefore, there is a problem that the ion beam collides with peripheral members other than the target.

The collision of the ion beam advances sputtering of the target peripheral member, for example, an anti-adhesion shield, and causes the sputtered particles to generate. In the case where the sputtered particles generated in the target peripheral member are mixed into the formed thin film, contamination (hereinafter, sometimes referred to as “contamination originating from the target peripheral member” in the description of the present application) is generated in the formed thin film.

In the case where the contamination originating from the target peripheral member is generated in the high refractive index layer and the low refractive index layer that constitute the reflective multilayer film, the refractive indices of these layers change. Accordingly, there is a concern that the reflectance decreases. In this case, a peak reflectance of a light in an EUV wavelength region on a surface of the reflective multilayer film is locally low at a site where the contamination is generated. As a result, an intensity of the peak reflectance of the light in the EUV wavelength region is reduced on the surface of the reflective multilayer film.

Once the intensity of the peak reflectance of the light in the EUV wavelength region is reduced on the surface of the reflective multilayer film, there is a concern that an amount of EUV exposure applied to a resist on a wafer is insufficient when the EUV lithography is performed using a reflective mask made from a reflective mask blank. This results in insufficient patterning within an exposure field, which is a factor that hinders a high precision patterning.

An object of the present invention is to provide a reflective mask blank excellent in reflectance characteristics of a reflective multilayer film, a production method therefor, and a substrate with a reflection layer for the mask blank.

As a result of intensive studies, the present inventors have found that the above object can be solved by the following configuration.
1. A method for producing a reflective mask blank, including:
   forming a reflective multilayer film on or above a substrate by using an ion beam sputtering apparatus and a process gas, the ion beam sputtering apparatus accelerating an ion generated by applying a voltage to a grid, and causing the ion to collide with a target to perform sputtering, the process gas including at least one inert gas selected from He, Ne, Ar, Kr, Xe, Rn, and N₂ as an ion source, in which
   a product of an effective area (cm²) of the grid and a flow rate (sccm) of the process gas supplied to the ion beam sputtering apparatus during film formation is 3600 (cm²·sccm) or less.
2. The method for producing a reflective mask blank according to item 1, in which an anti-adhesion shield is disposed to cover the target in the ion beam sputtering apparatus.
3. The method for producing a reflective mask blank according to item 2, in which a constituent material of the anti-adhesion shield includes at least one element selected from the group consisting of Al, Fe, Cr, Ni, Y, Cu, Mn, Zn, Si, Mg, V Sn, Mo, and Zr
4. The method for producing a reflective mask blank according to any one of items 1 to 3, in which the product of the effective area (cm²) of the grid and the flow rate (sccm) of the process gas supplied to the ion beam sputtering apparatus during film formation is 1000 (cm²·sccm) or more.
5. The method for producing a reflective mask blank according to any one of items 1 to 4, in which the process gas includes Ar.
6. A substrate with a reflection layer, including:
   a substrate;
   a reflection layer reflecting EUV light; and
   a protective layer for the reflection layer, in this order, in which
   the reflection layer is a reflective multilayer film formed by alternately laminating a low refractive index layer and a high refractive index layer a plurality of times, and
   when a metal atom having a highest content in the low refractive index layer is taken as a metal X, and a metal other than a metal being a constituent component of the substrate, a metal being a constituent component of the low refractive index layer, a metal being a constituent component of the high refractive index layer, and a metal being a constituent component of the protective layer is taken as a metal Y, in measuring the substrate with a reflection layer by fluorescent X-ray analysis, an intensity ratio of a peak attributed to the metal Y to a peak attributed to the metal X (an intensity of the peak attributed to the metal Y/an intensity of the peak attributed to the metal X) is 0.0060 or less.
7. The substrate with a reflection layer according to item 6, in which the metal Y is at least one element selected from the group consisting of Al, Fe, Cr, Ni, Y, Cu, Mn, Zn, Si, Mg, V, Sn, Mo, and Zr.
8. The substrate with a reflection layer according to item 6 or 7, in which the low refractive index layer includes Mo.
9. The substrate with a reflection layer according to item 8, in which the metal Y is at least one element selected from the group consisting of Al, Fe, Cr, Ni, Y, Cu, Mn, Zn, Si, Mg, V, Sn, and Zr.
10. The substrate with a reflection layer according to any one of items 6 to 9, in which the high refractive index layer includes Si.
11. A reflective mask blank including:
   the substrate with a reflection layer according to any one of items 6 to 10; and
   an absorption layer on or above the protective layer of the substrate with a reflection layer, the absorption layer absorbing EUV light.
12. The reflective mask blank according to item 11, further including a low reflection layer on or above the absorption layer, the low reflection layer being for an inspection light used for a mask pattern inspection.
13. A reflective mask obtained by patterning the reflective mask blank according to item 11 or 12.

The present invention can provide a reflective mask blank excellent in reflectance characteristics of a reflective multilayer film, a production method therefor, and a substrate with a reflection layer for the mask blank.

### BRIEF DESCRIPTION OF DRAWINGS

FIG. 1 is a schematic cross-sectional view showing a substrate with a reflection layer according to an embodiment of the present invention.

FIG. 2 is a schematic cross-sectional view showing a reflective mask blank according to an embodiment of the present invention.

### DESCRIPTION OF EMBODIMENTS

Hereinafter, an embodiment of the present invention will be described.

First, a method for producing a reflective mask blank according to the present embodiment will be described.

The method for producing a reflective mask blank according to the present embodiment includes a procedure of forming a reflective multilayer film on or above a substrate by using an ion beam sputtering apparatus and a process gas, the ion beam sputtering apparatus accelerating an ion generated by applying a voltage to a grid, and causing the ion to collide with a target to perform sputtering, the process gas containing at least one inert gas selected from He, Ne, Ar, Kr, Xe, Rn, and N2 as an ion source.

In the procedure of forming the reflective multilayer film on or above the substrate, a reflective multilayer film is formed, using the above ion beam sputtering apparatus, by alternately laminating a low refractive index layer having a low refractive index with respect to EUV light and a high refractive index layer having a high refractive index with respect to EUV light on or above the substrate.

The present inventors have obtained the following findings regarding generation of contamination originating from a target peripheral member in the reflective multilayer film formed on or above the substrate using the above ion beam sputtering apparatus.
(1) In the case where a flow rate F of the process gas supplied to the ion beam sputtering apparatus during film formation was reduced, an amount of the contamination originating from the target peripheral member in the formed reflective multilayer film was reduced. It is presumed that this is because in the case where the flow rate of the process gas during film formation was reduced, a mean free path for an ion beam was extended, and sputtering of the target peripheral member such as an anti-adhesion shield due to collision of the ion beam with the target peripheral member was less likely to occur.
(2) In the case where an effective area S of a grid was reduced, the amount of the contamination originating from the target peripheral member in the formed reflective multilayer film was reduced. It is presumed that this is because the effective area of the grid that extract the ion beam was reduced, so that an irradiation diameter when the ion beam reached a site where the target was disposed was reduced even in the case where a diffusion angle was the same, making the ion beam less likely to collide with the target peripheral member.

Based on the above findings, the present inventors have found that in the case where a product (S×F) of the effective area S (cm²) of the grid and the flow rate F (sccm) of the process gas supplied to the ion beam sputtering apparatus during film formation is set to a predetermined value or less, the generation of the contamination originating from the target peripheral member in the reflective multilayer film can be prevented, and reflectance characteristics of the reflective multilayer film can be improved. Specifically, the present inventors have found that an intensity of a peak reflectance of light in an EUV wavelength region on a surface of the reflective multilayer film is improved by the above.

In the method for producing a reflective mask blank according to the present embodiment, the product (S×F) of the effective area S (cm²) of the grid and the flow rate F (sccm) of the process gas supplied to the ion beam sputtering apparatus during film formation is 3600 (cm²·sccm) or less. In the case where the product (S×F) of the effective area S of the grid and the flow rate F of the process gas during film formation satisfies the above range, the generation of the contamination originating from the target peripheral member in the reflective multilayer film can be prevented. Accordingly, the reflectance characteristics of the reflective multilayer film are improved. Specifically, in-plane uniformity of the peak reflectance of the light in the EUV wavelength region on the surface of the reflective multilayer film is improved.

In the method for producing a reflective mask blank according to the present embodiment, the product (S×F) of the effective area S (cm²) of the grid and the flow rate F (sccm) of the process gas during film formation is preferably 3000 (cm²·sccm) or less, and more preferably 2500 (cm²·sccm) or less.

In the method for producing a reflective mask blank according to the present embodiment, the product (S×F) of the effective area S (cm²) of the grid and the flow rate F (sccm) of the process gas during film formation is preferably 1000 (cm²·sccm) or more, more preferably 1500 (cm²·sccm) or more, and still more preferably 1800 (cm²·sccm) or more. In the case where the product (S×F) of the effective area S of the grid and the flow rate F of the process gas during film formation is 1000 (cm²·sccm) or more, it is excellent from the view point that electrons are generated by gas collision in the ion beam sputtering apparatus, and the ion beam is sufficiently neutralized by the electrons.

In the description of the present application, the effective area S (cm²) of the grid refers to an area of a site in the grid provided with lattice-shaped openings. The effective area S of the grid is calculated using the following equation.

S=π×r² (cm²)

In the above equation, r is a radius (cm) of the site in the grid provided with lattice-shaped openings, and is obtained by multiplying a nominal diameter (cm) of the site in the grid provided with lattice-shaped openings by ½. The shape of the site in the grid provided with lattice-shaped openings is often circular. However, in the case where the shape of the site in the grid provided with lattice-shaped openings is not circular, a circle-equivalent diameter of the site in the grid provided with lattice-shaped openings is obtained, and r is obtained therefrom.

The effective area S of the grid is preferably 200 cm² or less. In the case where the effective area S of the grid is preferably 200 cm² or less, the irradiation diameter when the ion beam reaches the site where the target is disposed is reduced even in the case where the diffusion angle is the same, making the ion beam less likely to collide with the target peripheral member. Therefore, it is excellent in preventing the generation of the contamination originating from the target peripheral member in the reflective multilayer film. The effective area S of the grid is more preferably 190 cm² or less.

The effective area S of the grid is preferably 100 cm² or more. It is excellent in terms of productivity of the reflective mask blank in the case where the effective area S of the grid is 100 cm² or more. The effective area S of the grid is more preferably 110 cm² or more.

The flow rate F of the process gas supplied to the ion beam sputtering apparatus during film formation is preferably 18 sccm or less. In the case where the flow rate F of the process gas during film formation is 18 sccm or less, the mean free path for the ion beam is extended, and sputtering of the target peripheral member due to collision of the ion beam with the target peripheral member is less likely to occur. Therefore, it is excellent in preventing the generation of the contamination originating from the target peripheral member in the reflective multilayer film.

The flow rate F of the process gas during film formation is preferably 5 sccm or more. In the case where the flow rate F of the process gas during film formation is 5 sccm or more, it is excellent in terms of discharge stability.

In the method for producing a reflective mask blank according to the present embodiment, the process gas supplied to the ion beam sputtering apparatus may contain only one of He, Ne, Ar, Kr, Xe, Rn, and N₂, or may contain two or more of them.

The process gas supplied to the ion beam sputtering apparatus preferably contains Ar in terms of economic efficiency and ease of discharge.

In the method for producing a reflective mask blank according to the present embodiment, ion beam sputtering may be performed by selecting a sputtering target according to the reflective multilayer film to be formed.

For example, in the case where the reflective multilayer film is a Mo/Si reflective multilayer film, a Mo target is used as the target, a process gas containing at least one inert gas selected from He, Ne, Ar, Kr, Xe, Rn, and N₂ is used as the ion source, a voltage is applied to the grid to accelerate the generated ion, and the ion is caused to collide with the Mo target to perform sputtering, thereby forming a Mo layer as a low refractive index layer.

Next, a Si target is used as the target, a process gas containing at least one inert gas selected from He, Ne, Ar, Kr, Xe, Rn, and N₂ is used as the ion source, a voltage is applied to the grid to accelerate the generated ion, and the ion is caused to collide with the Si target to perform sputtering, thereby forming a Si layer as a high refractive index layer. This procedure is alternately repeated to form a reflective multilayer film in which Mo layers and Si layers are alternately laminated a predetermined number of times on or above the substrate.

In the method for producing a reflective mask blank according to the present embodiment, ion beam sputtering conditions during formation of the reflective multilayer film other than the effective area S of the grid and the flow rate F of the process gas during film formation are appropriately selected according to the reflective multilayer film to be formed.

In the case where the reflective multilayer film is a Mo/Si reflective multilayer film, the beam voltage is preferably 100 V to 1500 V, more preferably 150 V to 1200 V, and still more preferably 200 V to 1000 V A pressure in a chamber is preferably 1.0 Pa or less, more preferably 1.0×10⁻¹ Pa or less, still more preferably 8.0×10⁻² Pa or less, and particularly preferably 6.0×10⁻² Pa or less.

It is preferable that the ion beam sputtering apparatus for use in the method for producing a reflective mask blank according to the present embodiment have an anti-adhesion shield to cover the target, in order to prevent foreign matters from adhering to the target. The target and the anti-adhesion shield disposed around the target may be rotated, and Al, which is lighter than SUS (stainless steel), may be used in consideration of a load on a servomotor. Therefore, the sputtering apparatus may be provided with an anti-adhesion plate to prevent deposition of a film in the chamber, but the anti-adhesion plate and the anti-adhesion shield are generally different in material and pretreatment.

A constituent material of the anti-adhesion shield is not particularly limited, and preferably contains at least one element selected from the group consisting of Al, Fe, Cr, Ni, Y, Cu, Mn, Zn, Si, Mg, V, Sn, Mo, and Zr, and more preferably contains Al for reasons of workability and material stability during use. The constituent material of the anti-adhesion shield may contain two or more of the above elements.

In the method for producing a reflective mask blank according to the present embodiment, there is no particular limitation other than the procedure of forming the reflective multilayer film on or above the substrate. For example, the following procedures are performed.
a procedure of forming a protective layer for the reflective multilayer film on or above the reflective multilayer
a procedure of forming an absorption layer that absorbs EUV light on or above the protective layer

In the case where the reflective mask blank includes a low reflection layer for an inspection light used for a mask pattern inspection, the following procedure is further performed.
a procedure of forming a low reflection layer on or above the absorption layer

In the procedure of forming the protective layer, the protective layer is formed by using a known film forming method such as a magnetron sputtering method or an ion beam sputtering method. For example, in the case of forming a Ru layer as the protective layer using the above ion beam sputtering apparatus, a Ru target is used as the target, a process gas containing at least one inert gas selected from He, Ne, Ar, Kr, Xe, Rn, and N₂ is used as the ion source, a voltage is applied to the grid to accelerate the generated ion, and the ion is caused to collide with the Ru target to perform sputtering, thereby forming the Ru layer.

During the ion beam sputtering, the effective area S (cm²) of the grid, the flow rate F (sccm) of the process gas during film formation, and the product (S×F) of the effective area S (cm²) of the grid and the flow rate F (sccm) of the process gas during film formation preferably satisfy the conditions described for the reflective multilayer film.

In addition, preferred ranges of the beam voltage and the pressure in the chamber are the same as those described for the reflective multilayer film.

In the procedure of forming the absorption layer, the absorption layer is formed by using a dry film forming method such as a sputtering method such as a magnetron sputtering method or an ion beam sputtering method.

For example, in the case of forming a TaNH layer as the absorption layer using a magnetron sputtering method, it is formed under the following conditions.
Target: Ta target
Sputtering gas: mixed gas containing Ar, N₂, and H₂ (H₂ gas concentration: 1 vol % to 30 vol %, N₂ gas concentration: 5 vol % to 75 vol %, Ar gas concentration: 10 vol % to 94 vol %, gas pressure: 0.5×10⁻¹ Pa to 1.0 Pa)
Supplied electric power: 300 W to 2000 W

In the procedure of forming the low reflection layer, the low reflection layer is formed by using a dry film forming method such as a sputtering method such as a magnetron sputtering method or an ion beam sputtering method.

For example, in the case of forming a TaON layer as the low reflection layer using a magnetron sputtering method, it is formed under the following conditions.
Target: Ta target
Sputtering gas: mixed gas containing Ar, O₂, and H₂ (O₂ gas concentration: 5 vol % to 80 vol %, N₂ gas concentration: 5 vol % to 75 vol %, Ar gas concentration: 5 vol % to 90 vol %, gas pressure: 1.0×10⁻¹ Pa to 50×10⁻¹ Pa)
Supplied electric power: 30 W to 1000 W

Next, a substrate with a reflection layer according to the present embodiment will be described. The substrate with a reflection layer is used as a precursor of the reflective mask blank.

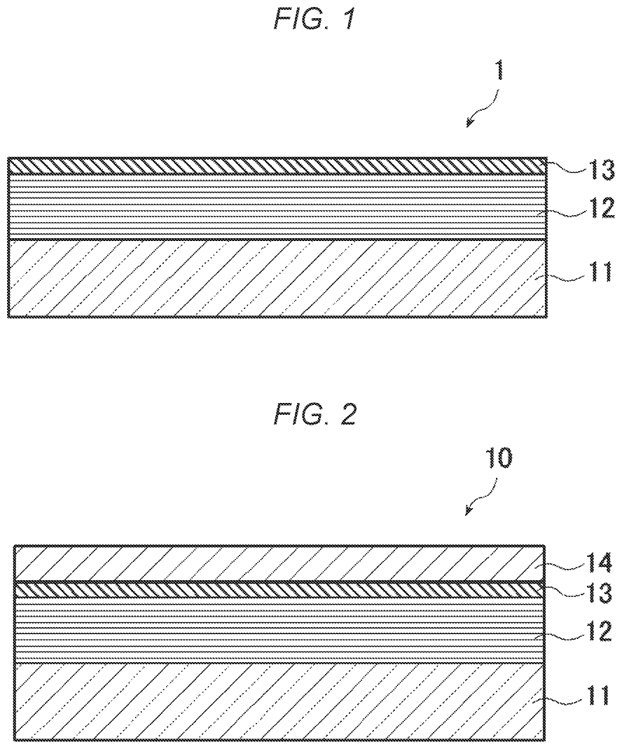

FIG. 1 is a schematic cross-sectional view showing a substrate with a reflection layer according to an embodiment of the present invention. A substrate with a reflection layer 1 shown in FIG. 1 includes a reflection layer 12 and a protective layer 13 for the reflection layer 12 formed in this order on or above a substrate 11. The reflection layer 12 is a reflective multilayer film formed by alternately laminating a low refractive index layer and a high refractive index layer a plurality of times.

The substrate with a reflection layer according to the present invention is produced by the method for producing a reflective mask blank according to the present invention.

In the substrate with a reflection layer according to the present embodiment, when a metal atom having a highest content in the low refractive index layer is taken as a metal X, and a metal other than a metal being a constituent component of the substrate 11, a metal being a constituent component of the low refractive index layer, a metal being a constituent component of the high refractive index layer, and a metal being a constituent component of the protective layer 13 is taken as a metal Y, in measuring the substrate with a reflection layer by fluorescent X-ray analysis (XRF), an intensity ratio of a peak attributed to the metal Y to a peak attributed to the metal X (intensity of peak attributed to metal Y/intensity of peak attributed to metal X) is 0.0060 or less.

The reason why the metal atom having the highest content in the low refractive index layer is taken as the metal X is described below.

A molybdenum (Mo) layer is generally used as the low refractive index layer and a silicon (Si) layer is generally used as the high refractive index layer in the reflective multilayer film. Therefore, a metal atom having a highest content in the high refractive index layer is generally Si. On the other hand, a SiO₂—TiO₂ glass is generally used for the substrate and the substrate contains Si. In measuring the substrate with a reflection layer by XRF, Si in the substrate underlying the reflective multilayer film may be detected, and it may be difficult to identify a peak attributed to Si in the reflective multilayer film.

On the other hand, the metal atom having the highest content in the low refractive index layer is generally Mo. The substrate underlying the reflective multilayer film generally does not contain Mo. Therefore, in measuring the substrate with a reflection layer by XRF, it is easy to identify a peak attributed to Mo in the reflective multilayer film.

In the case where there are two or more types of metal atoms having the highest content in the low refractive index layer, any one of these metal atoms is taken as the metal X.

In the description of the present application, the metal being the constituent component of the substrate 11 refers to a metal that is intentionally blended as the constituent component of the substrate 11. Metals mixed into the substrate 11 as impurities are not included. The same applies to the metal being the constituent component of the low refractive index layer, the metal being the constituent component of the high refractive index layer, and the constituent component of the protective layer. Therefore, a representative example of the metal Y includes a metal forming the contamination originating from the target peripheral member in the reflective multilayer film, for example, Al, Fe, Cr, Ni, Y, Cu, Mn, Zn, Si, Mg, V, Sn, Mo, and Zr.

In the case where the intensity ratio of the peak attributed to the metal Y to the peak attributed to the metal X (intensity of peak attributed to metal Y/intensity of peak attributed to metal X) is 0.0060 or less in measuring the substrate with a reflection layer by XRF, an amount of the metal Y forming the contamination originating from the target peripheral member in the reflective multilayer film is extremely small with respect to an amount of the metal X forming the low refractive index layer of the reflective multilayer film. Therefore, a reduction in intensity of the peak reflectance of the light in the EUV wavelength region on the surface of the reflective multilayer film is prevented.

The intensity ratio of the peak attributed to the metal Y to the peak attributed to the metal X (intensity of peak attributed to metal Y/intensity of peak attributed to metal X) is preferably 0.0055 or less, and more preferably 0.0050 or less. The intensity ratio of the peak attributed to the metal Y to the peak attributed to the metal X (intensity of peak attributed to metal Y/intensity of peak attributed to metal X) is preferably 0.00001 or more.

In the case where two or more elements are detected as the metal Y, the maximum value of intensities of peaks attributed to these elements is taken as the intensity of the peak attributed to the metal Y.

The substrate with a reflection layer according to the present embodiment will be further described.

The substrate 11 satisfies characteristics as a substrate for an EUV mask blank. Therefore, the substrate 11 has a low thermal expansion coefficient (specifically, a thermal expansion coefficient at 20° C. of preferably 0±0.05×10⁻⁷/° C., and more preferably 0±0.03×10⁻⁷/° C.), and is excellent in smoothness, flatness, and resistance to a cleaning liquid for use in cleaning a mask blank or a photomask after pattern formation. As the substrate 11, specifically, a glass having a low thermal expansion coefficient, for example, a SiO₂—TiO₂ glass is used, but the substrate 11 is not limited thereto. A substrate made of a crystallized glass in which a β-quartz solid solution is precipitated, a quartz glass, silicon, a metal, or the like can also be used.

It is preferable that the substrate 11 have a smooth surface having a surface roughness (rms) of 0.15 nm or less and have a flatness of 100 nm or less since a high reflectance and transfer accuracy can be obtained in a photomask after pattern formation.

A size, thickness, and the like of the substrate 11 are appropriately determined according to design values and the like of the mask.

It is preferable that no defect be present on a surface of the substrate 11 on which the reflective multilayer film is formed. However, even in the case where defects are present, recessed defects and/or protruding defects should not generate phase defects. Specifically, a depth of a recessed defect and a height of a protruding defect are preferably 2 nm or less, and a half width of the recessed defect and the protruding defect is preferably 60 nm or less. The half width of the recessed defect refers to a width at a depth position that is ½ of the depth of the recessed defect. The half width of the protruding defect refers to a width at a height position that is ½ of the height of the protruding defect.

Regarding the reflective multilayer film, a high EUV light reflectance is achieved by alternately laminating the high refractive index layer and the low refractive index layer a plurality of times. In the reflective multilayer film, Si is widely used for the high refractive index layer, and Mo is widely used for the low refractive index layer. That is, the Mo/Si reflective multilayer film is the most common.

The reflective multilayer film is not particularly limited as long as it has desired characteristics as the reflection layer in the reflective mask blank. Here, the characteristic particularly required for the reflective multilayer film is a high EUV light reflectance. Specifically, the peak reflectance of the light in the EUV wavelength region (that is, the local maximum value of the light reflectance near a wavelength of 13.5 nm, and hereinafter referred to as the “peak reflectance of EUV light” in the description of the present application) is preferably 60% or more, and more preferably 65% or more, when the surface of the reflective multilayer film is irradiated with the light in the EUV wavelength region at an incident angle of 6 degrees. In addition, even in the state where the protective layer 13 is provided on the reflective multilayer film, the peak reflectance of the EUV light is preferably 60% or more, and more preferably 65% or more.

A film thickness of each of the layers constituting the reflective multilayer film and the number of repeating units of the layer can be appropriately selected according to a film material to be used and the EUV light reflectance required for the reflection layer. Taking the Mo/Si reflective multilayer film as an example, in order to obtain a reflective multilayer film in which the maximum value of the EUV light reflectance is 60% or more, the reflective multilayer film may be formed by laminating a Mo layer having a film thickness of 2.3 nm±0.1 nm and a Si layer having a film thickness of 4.5 nm±0.1 nm at a number of repeating units of 30 to 60.

In order to prevent oxidation of the surface of the reflective multilayer film, it is preferable that the uppermost layer of the reflective multilayer film be a layer made of a hardly oxidized material. The layer made of a hardly oxidized material functions as a cap layer for the reflective multilayer film. Specific examples of the layer made of a hardly oxidized material and functioning as a cap layer include a Si layer. In the case where the reflective multilayer film is the Mo/Si reflective multilayer film, the uppermost layer functions as a cap layer by using the Si layer as the uppermost layer. In this case, a film thickness of the cap layer is preferably 11 nm±2 nm.

(Protective Layer)

The protective layer 13 is provided for the purpose of protecting the reflective multilayer film such that when a pattern is to be formed on the absorption layer 14 by an etching process, generally a dry etching process, the reflective multilayer film is not damaged by the etching process. Therefore, as a material of the protective layer, a material which is hardly influenced by the etching process for the absorption layer 14, that is, a material which has a slower etching rate than that of the absorption layer 14 and is hardly damaged by the etching process is selected. In order to satisfy the above characteristics, the protective layer 13 preferably contains Ru.

A film thickness of the protective layer 13 is preferably 1 nm to 60 nm, and more preferably 1 nm to 40 nm.

Next, a reflective mask blank according to the present embodiment will be described.

FIG. 2 is a schematic cross-sectional view showing a reflective mask blank according to an embodiment of the present invention. A reflective mask blank 10 shown in FIG. 2 includes the reflection layer 12, the protective layer 13, and the absorption layer 14 formed in this order on or above the substrate 11. The reflective mask blank 10 shown in FIG. 2 is formed by forming the absorption layer 14 on the protective layer 13 of the substrate with a reflection layer 1 shown in FIG. 1.

A characteristic particularly required for the absorption layer 14 is an extremely low EUV light reflectance. Specifically, the peak reflectance of the EUV light is preferably 5% or less, more preferably 3% or less, and particularly preferably 1% or less when a surface of the absorption layer 14 is irradiated with the light in the EUV wavelength region.

In order to achieve the above characteristic, the absorption layer 14 is made of a material having a high EUV light absorption coefficient. The material having a high EUV light absorption coefficient is preferably a material containing tantalum (Ta) as a main component. In the description of the present application, a material containing tantalum (Ta) as a main component means a material containing 20 at % or more of Ta in the material.

The material containing Ta as a main component for use in the absorption layer 14 preferably contains, in addition to Ta, at least one component selected from hafnium (Hf), Si, zirconium (Zr), germanium (Ge), boron (B), palladium (Pd), tin (Sn), chromium (Cr), manganese (Mn), iron (Fe), cobalt (Co), silver (Ag), cadmium (Cd), indium (In), antimony (Sb), tungsten (W), rhenium (Re), osmium (Os), iridium (Ir), platinum (Pt), gold (Au), thallium (Tl), lead (Pb), bismuth (Bi), carbon (C), titanium (Ti), zirconium (Zr), Mo, Ru, rhodium (Rh), palladium (Pd), calcium (Ca), magnesium (Mg), Al, nickel (Ni), copper (Cu), zinc (Zn), gallium (Ga), arsenic (As), selenium (Se), tellurium (Te), hydrogen (H), and nitrogen (N). Specific examples of the material containing the above elements in addition to Ta include TaN, TaNH, TaHf, TaHfN, TaBSi, TaBSiN, TaB, TaBN, TaSi, TaSiN, TaGe, TaGeN, TaZr, TaZrN, TaPd, TaSn, TaPdN, TaSn, TaCr, TaMn, TaFe, TaCo, TaAg, TaCd, TaIn, TaSb, and TaW.

The absorption layer 14 preferably has a film thickness of 20 nm to 90 nm.

Further, in the reflective mask blank according to the present embodiment, a low reflection layer for an inspection light used for the mask pattern inspection may be formed on the absorption layer 14.

The low reflection layer is formed of a film having low reflection under the inspection light used for the mask pattern inspection. When preparing a reflective mask, a pattern is formed on the absorption layer, and then whether the pattern is formed as designed is inspected.

In the mask pattern inspection, an inspection machine with a light of about 257 nm as the inspection light is generally used. That is, the inspection is performed based on a difference in reflectance of the light of about 257 nm, specifically, a difference in reflectance between a surface exposed by removing the absorption layer in the pattern formation and a surface of the absorption layer remaining without being removed in the pattern formation. Here, the former is a surface of the protective layer. Therefore, in the case where the difference in reflectance between the surface of the protective layer and the surface of the absorption layer for the wavelength of the inspection light is small, a contrast during the inspection deteriorates, and accurate inspection cannot be performed. In the case where the difference in reflectance between the surface of the protective layer and the surface of the absorption layer for the wavelength of the inspection light is small, the contrast during the inspection is good due to the formation of the low reflection layer.

In the case of forming the low reflection layer on or above the absorption layer, the low reflection layer has a maximum reflectance of preferably 15% or less, more preferably 10% or less, and still more preferably 5% or less at the wavelength of the inspection light when a surface of the low reflection layer is irradiated with light in the wavelength region of the inspection light.

In order to achieve the above characteristic, the low reflection layer is preferably made of a material having a lower refractive index at the wavelength of the inspection light than that of the absorption layer.

The low reflection layer satisfying this characteristic may contain at least one selected from the group consisting of Ta, Pd, Cr, Si, and Hf, and at least one selected from the group consisting of oxygen (O) and N. Preferred examples of such a low reflection layer include a TaPdO layer, a TaPdON layer, a TaON layer, a CrO layer, a CrON layer, a SiON layer, a SiN layer, a HfO layer, and a HfON layer.

The reflective mask blank 10 according to the present embodiment may include a functional film known in the field of reflective mask blanks, in addition to the reflective multilayer film, the protective layer 13, the absorption layer 14, and the low reflection layer formed as necessary. Specific examples of such a functional film include a high dielectric coating to be applied to a back surface side of a substrate in order to promote electrostatic chucking of the substrate, as described in JP2003-501823A.

By patterning at least the absorption layer (the absorption layer and the low reflection layer in the case where the low reflection layer is formed on the absorption layer) of the reflective mask blank according to the present embodiment, the reflective mask according to the present embodiment can be obtained.

### EXAMPLES

Hereinafter, the present invention will be described in more detail using Examples, but the present invention is not limited to these Examples. Among Example 1 to Example 4, Example 1 to Example 3 are inventive examples, and Example 4 is a comparative example.

### Example 1

In Example 1, the substrate with a reflection layer 1 shown in FIG. 1 was prepared. As the substrate 11 for film formation, a SiO₂—TiO₂ glass substrate (outer shape: 6-inch (152-mm) square, thickness: 6.3 mm) was used. This glass substrate had a thermal expansion coefficient at 20° C. of 0.02×10⁻⁷/° C., a Young's modulus of 67 GPa, a Poisson's ratio of 0.17, and specific stiffness of 3.07×10⁷ m²/s². This glass substrate was polished to form a smooth surface having a surface roughness (rms) of 0.15 nm or less and having a flatness of 100 nm or less.

On a back surface side of the substrate 11, a Cr film having a thickness of 100 nm was formed using a magnetron sputtering method, thereby applying a high dielectric coating having a sheet resistance of 100 Ω/sq.

The substrate 11 (outer shape: 6-inch (152-mm) square, thickness: 6.3 mm) was fixed to a general electrostatic chuck having a flat plate shape via the formed Cr film, and a cycle of alternately forming a Mo film and a Si film on the surface of the substrate 11 using an ion beam sputtering method was repeated 40 times, so as to form a Mo/Si reflective multilayer film having a total film thickness of 272 nm ((2.3 nm+4.5 nm)×40) as the reflection layer 12.

Further, a Ru layer having a film thickness of 2.5 nm was formed as the protective layer 13 on the Mo/Si reflective multilayer film using an ion beam sputtering method.

In the ion beam sputtering apparatus used, an anti-adhesion shield made of Al is disposed to cover a target. A site in the grid provided with lattice-shaped openings is circular. Note that, as the anti-adhesion shield, an anti-adhesion shield whose outermost surface was thermally sprayed with Al was used.

As the process gas, an Ar gas was used. The flow rate F of Ar, as the process gas, during film formation, the nominal diameter of the site in the grid provided with lattice-shaped openings (in the table below, written as “nominal diameter of grid”), the radius r of the site in the grid provided with lattice-shaped openings, the effective area S of the grid, and the product (S×F) of the effective area S of the grid and the flow rate F of Ar, as the process gas, during film formation are as shown in the table below. The beam voltage was 600 V and the pressure in a chamber was 2.7×10⁻² Pa.

In the obtained substrate with a reflection layer, the metal X having the highest content in the low refractive index layer is Mo. The metal Y other than the metal being the constituent component of the substrate 11, the metal being the constituent component of the low refractive index layer, the metal being the constituent component of the high refractive index layer, and the metal being the constituent component of the protective layer 13 is Al. Therefore, the obtained substrate with a reflection layer was measured by XRF, and an intensity ratio of a peak attributed to Al to a peak attributed to Mo (intensity of peak attributed to Al/intensity of peak attributed to Mo) was obtained. The intensity of the peak was calculated using a net intensity obtained by subtracting background. Note that, the conditions of the XRF measurement are as follows.
X-ray source target bulb tube: Rh
Excitation voltage/X-ray power: 3 kW
Types of dispersive crystal
Al: PETH (pentaerythritol)
Mo: LiF (200)
Degree of vacuum: 7 Pa

Results are shown in the table below.

In addition, a surface of the Ru layer was irradiated with EUV light at an incident angle of 6 degrees. The reflected light in the EUV wavelength region at this time was measured using an EUV reflectometer, a minimum value in an in-plane distribution of the peak reflectance in the wavelength region was obtained, and a change rate of the peak reflectance was calculated based on the minimum value in the in-plane distribution of the peak reflectance in the wavelength region in Example 1. Note that, a positive value of the change rate of the peak reflectance represents an increase rate of the peak reflectance, and a negative value of the change rate of the peak reflectance represents a decrease rate of the peak reflectance. The change rate of the peak reflectance of the EUV light was evaluated according to the following criteria.
A: the change rate (%) of the peak reflectance of light in the EUV wavelength region is greater than 0.20%.
B: the change rate (%) of the peak reflectance of light in the EUV wavelength region is 0% or more and 0.20% or less.
C: the change rate (%) of the peak reflectance of light in the EUV wavelength region is less than 0% (the decrease rate (%) is more than 0%).

### Examples 2 to 4

A substrate with a reflection layer was prepared in the same procedure as in Example 1 under the conditions shown in the table below for the flow rate F of Ar, as the process gas, during film formation, the nominal diameter of the site in the grid provided with lattice-shaped openings, the radius r of the site in the grid provided with lattice-shaped openings, the effective area S of the grid, and the product (S×F) of the effective area S of the grid and the flow rate F of Ar, as the process gas, during film formation.

Next, the substrate with a reflection layer was measured by XRF, and an intensity ratio of a peak attributed to Al to a peak attributed to Mo (intensity of peak attributed to Al/intensity of peak attributed to Mo) was obtained. In addition, a surface of the Ru layer was irradiated with EUV light at an incident angle of 6 degrees. The reflected light in the EUV wavelength region at this time was measured using an EUV reflectometer, a minimum value in an in-plane distribution of the peak reflectance in the wavelength region was obtained, and a change rate of the peak reflectance was calculated based on the minimum value in the in-plane distribution of the peak reflectance in the wavelength region in Example 1.

### Example 5

A substrate with a reflection layer was prepared in the same procedure as in Example 1, except that an anti-adhesion shield whose outermost surface was thermally sprayed with Y₂O₃ (yttrium oxide) was used.

Next, the substrate with a reflection layer was measured by XRF, and an intensity ratio of a peak attributed to Al to a peak attributed to Mo (intensity of peak attributed to Al/intensity of peak attributed to Mo) was obtained. Next, under the following conditions, the substrate with a reflection layer was measured by XRF, and an intensity ratio of a peak attributed to Y (yttrium) to a peak attributed to Mo (intensity of peak attributed to Y (yttrium)/intensity of peak attributed to Mo) was obtained. Note that, the intensity of the peak was calculated using a net intensity obtained by subtracting background.
X-ray source target bulb tube: Rh
Excitation voltage/X-ray power: 3 kW
Types of dispersive crystal
Y: PET (pentaerythritol)
Mo: LiF (200)
Degree of vacuum: 7 Pa

In addition, a surface of the Ru layer was irradiated with EUV light at an incident angle of 6 degrees. The reflected light in the EUV wavelength region at this time was measured using an EUV reflectometer, a minimum value in an in-plane distribution of the peak reflectance in the wavelength region was obtained, and a change rate of the peak reflectance was calculated based on the minimum value in the in-plane distribution of the peak reflectance in the wavelength region in Example 1.

TABLE 1

| | Intensity of peak | | Intensity of peak | | | |
|---|---|---|---|---|---|---|
| | attributed to | | attributed to Y | | | |
| | Al/intensity of | | (yttrium)/intensity of | | | |
| | peak attributed to Mo | | peak attributed to Mo | | Flow rate F (sccm) of Ar | |
| Example | 0.0054 | | — | | 17 | |
| 1 | | | | | | |
| Example | 0.0044 | | — | | 13 | |
| 2 | | | | | | |
| Example | 0.0048 | | — | | 17 | |
| 3 | | | | | | |
| Example | 0.0068 | | — | | 20 | |
| 4 | | | | | | |
| Example | 0.0006 | | 0.0009 | | 17 | |
| 5 | | | | | | |
| | Nominal | | | | Change rate (%) of | |
| | diameter (cm) | | Effective area S | S × F | peak reflectance of | |
| | of grid | r (cm) | (cm²) of grid | (sccm × cm²) | EUV light | Evaluation |
| Example | 15.2 | 7.6 | 182 | 3101 | 0.00 | B |
| 1 | | | | | | |
| Example | 15.2 | 7.6 | 182 | 2371 | 0.22 | A |
| 2 | | | | | | |
| Example | 12.1 | 6.0 | 114 | 1944 | 0.47 | A |
| 3 | | | | | | |
| Example | 15.2 | 7.6 | 182 | 3648 | −0.19 | C |
| 4 | | | | | | |
| Example | 15.2 | 7.6 | 182 | 3101 | 0.19 | B |
| 5 | | | | | | |

In each of Examples 1 to 3 in which the product (S×F) of the effective area S of the grid and the flow rate F of Ar, as the process gas, during film formation was 3600 (cm²·sccm) or less, the formed substrate with a reflection layer had an intensity ratio (intensity of peak attributed to Al/intensity of peak attributed to Mo) of 0.0060 or less, and an evaluation on the change rate of the peak reflectance of A or B. Therefore, there was no decrease in the peak reflectance. In Example 5 in which the product (S×F) of the effective area S of the grid and the flow rate F of Ar, as the process gas, during film formation was 3600 (cm²·sccm) or less, the formed substrate with a reflection layer had an intensity ratio (intensity of peak attributed to Y/intensity of peak attributed to Mo) of 0.0060 or less, and an evaluation on the change rate of the peak reflectance of B. Therefore, there was no decrease in the peak reflectance. In each of Examples 2 and 3 in which the product (S×F) of the effective area S of the grid and the flow rate F of Ar, as the process gas, during film formation was 2500 (cm²·sccm) or less, the formed reflective multilayer film had a intensity ratio (intensity of peak attributed to Al/intensity of peak attributed to Mo) of 0.0050 or less, a high change rate of the peak reflectance of the EUV light, and an evaluation on the change rate of A. In Example 4 in which the product (S×F) of the effective area S of the grid and the flow rate F of Ar, as the process gas, during film formation was more than 3600 (cm²·sccm), the formed substrate with a reflection layer had an intensity ratio (intensity of peak attributed to Al/intensity of peak attributed to Mo) of more than 0.0060, a decreased peak reflectance of the EUV light, and an evaluation on the change rate of C.

Although the present invention has been described in detail with reference to specific embodiments, it is apparent to those skilled in the art that various changes and modifications can be made without departing from the spirit and scope of the present invention. The present application is based on a Japanese patent application (No. 2021-082631) filed on May 14, 2021, and the contents thereof are incorporated herein by reference.

### REFERENCE SIGNS LIST

1: substrate with a reflection layer
10: reflective mask blank
11: substrate
12: reflection layer
13: protective layer
14: absorption layer

What is claimed is:

1. A method for producing a reflective mask blank, comprising:
forming a reflective multilayer film on or above a substrate by using an ion beam sputtering apparatus and a process gas, the ion beam sputtering apparatus accelerating an ion generated by applying a voltage to a grid, and causing the ion to collide with a target to perform sputtering, the process gas comprising at least one inert gas selected from He, Ne, Ar, Kr, Xe, Rn, and N₂ as an ion source, wherein
a product of an effective area (cm²) of the grid and a flow rate (sccm) of the process gas supplied to the ion beam sputtering apparatus during film formation is 3600 (cm²·sccm) or less.

2. The method for producing a reflective mask blank according to claim 1, wherein an anti-adhesion shield is disposed to cover the target in the ion beam sputtering apparatus.

3. The method for producing a reflective mask blank according to claim 2, wherein a constituent material of the anti-adhesion shield comprises at least one element selected from the group consisting of Al, Fe, Cr, Ni, Y, Cu, Mn, Zn, Si, Mg, V, Sn, Mo, and Zr.

4. The method for producing a reflective mask blank according to claim 1, wherein the product of the effective area (cm²) of the grid and the flow rate (sccm) of the process gas supplied to the ion beam sputtering apparatus during film formation is 1000 (cm²·sccm) or more.

5. The method for producing a reflective mask blank according to claim 1, wherein the process gas comprises Ar.

6. A substrate with a reflection layer, comprising:
a substrate;
a reflection layer reflecting EUV light; and
a protective layer for the reflection layer, in this order, wherein
the reflection layer is a reflective multilayer film formed by alternately laminating a low refractive index layer and a high refractive index layer a plurality of times, and
when a metal atom having a highest content in the low refractive index layer is taken as a metal X, and a metal other than a metal being a constituent component of the substrate, a metal being a constituent component of the low refractive index layer, a metal being a constituent component of the high refractive index layer, and a metal being a constituent component of the protective layer is taken as a metal Y, in measuring the substrate with a reflection layer by fluorescent X-ray analysis, an intensity ratio of a peak attributed to the metal Y to a peak attributed to the metal X (an intensity of the peak attributed to the metal Y/an intensity of the peak attributed to the metal X) is 0.0060 or less.

7. The substrate with a reflection layer according to claim 6, wherein the metal Y is at least one element selected from the group consisting of Al, Fe, Cr, Ni, Y, Cu, Mn, Zn, Si, Mg, V, Sn, Mo, and Zr.

8. The substrate with a reflection layer according to claim 6, wherein the low refractive index layer comprises Mo.

9. The substrate with a reflection layer according to claim 8, wherein the metal Y is at least one element selected from the group consisting of Al, Fe, Cr, Ni, Y, Cu, Mn, Zn, Si, Mg, V, Sn, and Zr.

10. The substrate with a reflection layer according to claim 6, wherein the high refractive index layer comprises Si.

11. A reflective mask blank comprising:
the substrate with a reflection layer according to claim 6; and
an absorption layer on or above the protective layer of the substrate with a reflection layer, the absorption layer absorbing EUV light.

12. The reflective mask blank according to claim 11, further comprising a low reflection layer on or above the absorption layer, the low reflection layer being for an inspection light used for a mask pattern inspection.

13. A reflective mask obtained by patterning the reflective mask blank according to claim 11.
